(19) United States
(12) Patent Application Publication
(10) Pub. No.: US 2026/0120637 A1
(43) Pub. Date: Apr. 30, 2026

(54) ELECTRONIC DEVICE

(71) Applicant: Samsung Display Co., Ltd., Yongin-si (KR)

(72) Inventors: Jung Suk BANG, Yongin-si (KR); Taehyun KIM, Yongin-si (KR); Dongil YOO, Yongin-si (KR); Myunghun LIM, Yongin-si (KR)

(73) Assignee: Samsung Display Co., Ltd., Yongin-si (KR)

(21) Appl. No.: 19/334,268

(22) Filed: Sep. 19, 2025

(30) Foreign Application Priority Data
Oct. 25, 2024 (KR) 10-2024-0147154

(51) Int. Cl. G09G 3/3233; G09G 3/20; H10K 59/121; H10K 59/131

(52) U.S. Cl. CPC G09G 3/3233; H10K 59/1213; H10K 59/131; G09G 3/2007; G09G 2300/0426; G09G 2300/0819; G09G 2300/0842; G09G 2300/0847; G09G 2310/08; G09G 2320/0238; G09G 2320/08; G09G 2354/00

(57) ABSTRACT

Disclosed is an display panel including a substrate, insulating layers on the substrate, signal lines between the insulating layers, transistors connected to the signal lines, and a light emitting element connected to the transistors, wherein the signal lines include a first initialization line, a bias line, a bias scan line, a light emitting line, a compensation scan line, an initialization scan line, a writing scan line, a second initialization line, and a data line which are arranged, and a driving transistor among the transistors is between the compensation scan line and the initialization scan line on a plane defined by the first direction and the second direction.

### CROSS-REFERENCE TO RELATED APPLICATION(S)

This application is based on and claims priority under 35 U.S.C. § 119 to Korean Patent Application No. 10-2024-0147154 filed on Oct. 25, 2024, in the Korean Intellectual Property Office, the disclosure of which is herein incorporated by reference in its entirety.

### BACKGROUND

Embodiments of the present disclosure described herein relate to an electronic device, and more particularly, relate to an electronic device having improved display quality.

Generally, electronic equipment such as smartphones, digital cameras, laptop computers, navigation systems, and smart televisions that provide images to a user include electronic devices for displaying the images. The electronic device generates an image and provides the generated image to the user through a display screen.

The electronic device includes a plurality of pixels for generating an image and a plurality of lines connected to the pixels. The plurality of pixels are driven by receiving driving signals through the plurality of lines.

### SUMMARY

Embodiments of the present disclosure provide an electronic device having improved brightness.

According to an aspect of an example embodiment of the present disclosure, a display panel includes a substrate, insulating layers on the substrate, signal lines between the insulating layers, transistors connected to the signal lines, and a light emitting element connected to the transistors, wherein the signal lines include a first initialization line, a bias line, a bias scan line, a light emitting line, a compensation scan line, an initialization scan line, a writing scan line, and a second initialization line, which extend in a first direction and are arranged in a second direction crossing the first direction, and a data line extending in the second direction, and a driving transistor among the transistors is between the compensation scan line and the initialization scan line on a plane defined by the first direction and the second direction.

According to an aspect of an example embodiment of the present disclosure, a display panel includes signal lines, transistors connected to the signal lines, and a light emitting element connected to the transistors, wherein the signal lines include a bias line, a first initialization line, a bias scan line, a light emitting line, a compensation scan line, an initialization scan line, a writing scan line, and a second initialization line which extend in a first direction and are arranged in a second direction crossing the first direction, and a data line extending in the second direction, and a driving transistor among the transistors is disposed between the compensation scan line and the initialization scan line on a plane defined by the first direction and the second direction.

According to an aspect of an example embodiment of the present disclosure, an electronic device includes a window and a display panel disposed below the window, wherein the display panel includes a substrate, insulating layers disposed on the substrate, signal lines disposed between the insulating layers, transistors connected to the signal lines, and a light emitting element connected to the transistors, wherein the signal lines include a first initialization line, a bias line, a bias scan line, a light emitting line, a compensation scan line, an initialization scan line, a writing scan line, and a second initialization line, which extend in a first direction and are arranged in a second direction crossing the first direction, and a data line extending in the second direction, and a driving transistor among the transistors is disposed between the compensation scan line and the initialization scan line on a plane defined by the first direction and the second direction.

### BRIEF DESCRIPTION OF FIGURES

The above and other objects and features of the present disclosure will become apparent by describing in detail example embodiments thereof with reference to the accompanying drawings.

FIG. 1 is a perspective view of an electronic device according to one or more embodiments of the present disclosure.

FIG. 2 is a view illustrating an example cross section of the electronic device illustrated in FIG. 1.

FIG. 3 is a view illustrating an example cross section of a display panel illustrated in FIG. 2.

FIG. 4 is a block diagram of the electronic device illustrated in FIG. 1.

FIG. 5 is a view illustrating an equivalent circuit of any one pixel among pixels illustrated in FIG. 4.

FIG. 6 is a timing diagram of scan signals and light emitting signals for describing an operation of the pixel illustrated in FIG. 5.

FIG. 7 is a view illustrating an example cross section including a light emitting element, a first transistor, a fourth transistor, and a sixth transistor of the pixel illustrated in FIG. 5.

FIG. 8 is a plan view illustrating a lamination relationship of conductive layers included in a pixel circuit according to one or more embodiments of the present disclosure.

FIGS. 9A to 9G are plan views illustrating conductive patterns included in conductive layers of a pixel circuit according to one or more embodiments of the present disclosure.

FIG. 10 is a plan view illustrating conductive patterns included in conductive layers of a pixel circuit according to one or more embodiments of the present disclosure.

FIGS. 11 to 14 are schematic plan views illustrating an arrangement relationship of signal lines included in a pixel circuit according to one or more embodiments of the present disclosure.

### DETAILED DESCRIPTION

In the specification, the expression that a first component (or area, layer, part, portion, etc.) is “disposed on”, “connected with” or “coupled to” a second component means that the first component is directly disposed on and/or connected with and/or coupled to the second component or means that a third component is interposed therebetween.

The same reference numerals may refer to the same components. Further, in the drawings, the thickness, the ratio, and the dimension of components may be exaggerated for effective description of technical contents. The expression “and/or” may include one or more combinations which associated components are capable of defining. For example, the expression “A and/or B” should be understood as including only a, only b, and both a and b.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, one or more example embodiments of the present disclosure will be described with reference to the accompanying drawings.

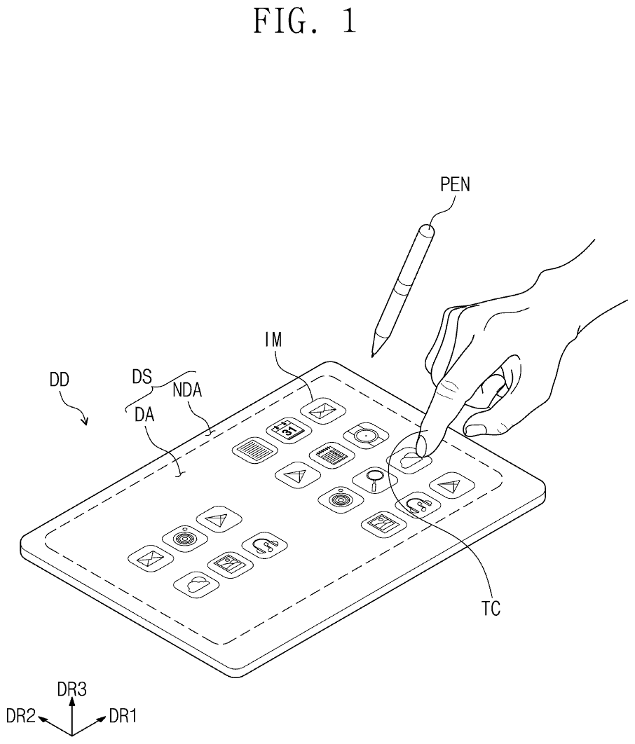

FIG. 1 is a perspective view of an electronic device according to one or more embodiments of the present disclosure.

Referring to FIG. 1, an electronic device DD according to one or more embodiments of the present disclosure may have a first side extending parallel to a first direction DR1 and a second side extending parallel to a second direction DR2 crossing (e.g., intersecting) the first direction DR1. A corner of the electronic device DD, at which the first side meets the second side, may have a curved shape. The corner of the electronic device DD, which has a curved shape, may be referred to as a rounded corner. A shape of the electronic device DD may be a quadrangle having a rounded corner (or a rounded corner quadrangle).

Hereinafter, a direction substantially perpendicular to a plane defined by the first direction DR1 and the second direction DR2 may be defined as a third direction DR3. Further, in the specification, the meaning “when viewed on a plane” may be defined as a state of being viewed from the third direction DR3.

A front surface of the electronic device DD may be defined as a display surface DS and may be on the plane defined by the first direction DR1 and the second direction DR2. An image IM generated by the electronic device DD may be provided to a user through the display surface DS.

The display surface DS may include a display area DA and a non-display area NDA around the display area DA. The display area DA may display an image, and the non-display area NDA may not display an image. The non-display area NDA may surround the display area DA and may define an edge of the electronic device DD printed in a predetermined color.

The display area DA may have a shape of a rounded corner quadrangle according to the shape of the electronic device DD. For example, the display area DA may include sides of a quadrangle respectively extending in the first direction DR1 and the second direction DR2 and rounded corners at which the sides meet. Sides extending in the first direction DR1 among the four sides may be defined as long sides, and sides extending in the second direction DR2 among the four sides may be defined as short sides.

The electronic device DD may sense an input applied from an outside of the electronic device DD. For example, the electronic device DD may sense a first input by a touch pen PEN and a second input by a touch TC. The touch pen PEN may be one example of an input device.

The touch pen PEN may be an active pen that outputs a signal. The second input by the touch TC may include various types of external inputs such as, for example but not limited to, a portion of a body of the user, light, heat, and/or pressure.

The electronic device DD and the touch pen PEN may communicate with each other in two directions. The electronic device DD may provide an uplink signal to the touch pen PEN. For example, the uplink signal may include information such as panel information and a protocol version, but the present disclosure is not limited thereto.

The touch pen PEN may provide a downlink signal to the electronic device DD. The downlink signal may include a synchronization signal and/or status information of the touch pen PEN. For example, the downlink signal may include coordinate information of the touch pen PEN, battery information of the touch pen PEN, inclination information of the touch pen PEN and/or various pieces of information stored in the touch pen PEN, but the present disclosure is not particularly limited thereto.

The electronic device DD may be used in large-sized electronic devices such as televisions, monitors, or external billboards. Further, the electronic device DD may be used in small and medium-sized electronic devices such as personal computers, laptop computers, personal digital terminals, vehicle navigation systems, game consoles, smartphones, tablets, or cameras. However, these are merely examples, and the electronic device DD may also be used in other electronic devices without departing from the concept of the present disclosure.

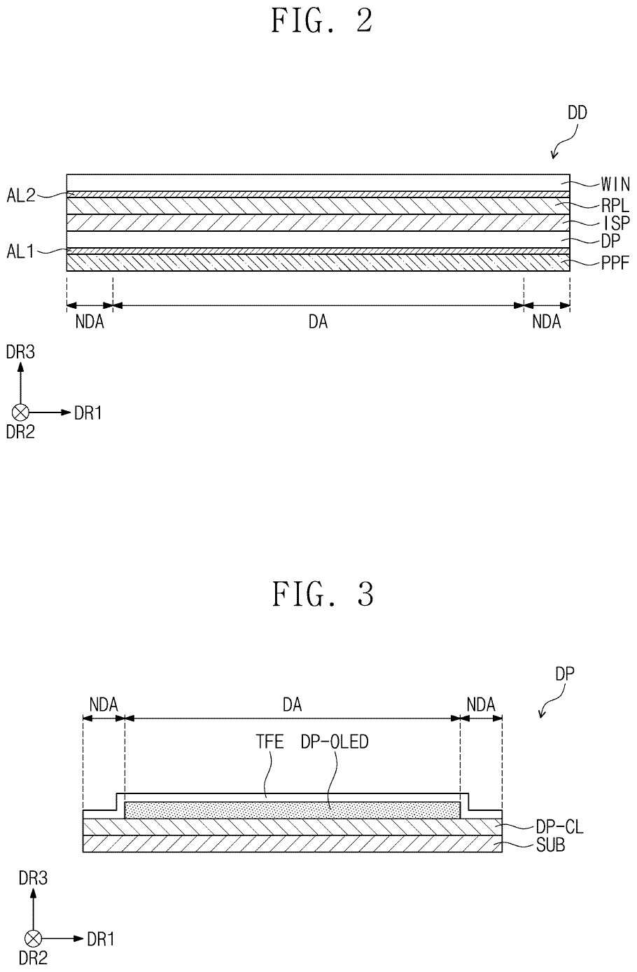

FIG. 2 is a view illustrating an example cross section of the electronic device illustrated in FIG. 1.

As an example, FIG. 2 illustrates a cross section of the electronic device DD when viewed in the second direction DR2.

Referring to FIG. 2, the electronic device DD may include a display panel DP, an input sensing unit ISP, a reflection preventing layer RPL, a window WIN, a panel protecting film PPF, a first adhesive layer AL1, and a second adhesive layer AL2.

The display panel DP according to one or more embodiments of the present disclosure may be a light emitting display panel. For example, the display panel DP may be an organic light emitting display panel or an inorganic light emitting display panel. A light emitting layer of the organic light emitting display panel may include an organic light emitting material. A light emitting layer of the inorganic light emitting display panel may include a quantum dot, a quantum rod, etc. Hereinafter, for illustrative purposes, the display panel DP will be described as the organic light emitting display panel.

The input sensing unit ISP may be disposed on the display panel DP. The input sensing unit ISP may include a plurality of sensing units (not illustrated) for sensing an external input in a capacitive manner. When the electronic device DD is manufactured, the input sensing unit ISP may be directly manufactured on the display panel DP. However, the present disclosure is not limited thereto, and the input sensing unit ISP may be manufactured as a separate panel from the display panel DP and attached to the display panel DP, for example, by using an adhesive layer.

The reflection preventing layer RPL may be disposed on the input sensing unit ISP. The reflection preventing layer RPL may be directly manufactured on the input sensing unit ISP when the electronic device DD is manufactured. However, the present disclosure is not limited thereto, and the reflection preventing layer RPL may be manufactured as a separate panel and attached to the input sensing unit ISP, for example, by using an adhesive layer.

The reflection preventing layer RPL may include an external light reflection preventing film. The reflection preventing layer RPL may reduce a reflectance of an external light incident from an upper side of the electronic device DD toward the display panel DP. The external light may not be visually recognized by the user due to the reflection preventing layer RPL.

When an external light traveling toward the display panel DP is reflected by the display panel DP and provided back to the user, the user may visually recognize the external light as in a case of a mirror. To prevent this phenomenon, for example, the reflection preventing layer RPL may include a plurality of color filters that display the same colors as those of corresponding pixels of the display panel DP.

The plurality of color filters may filter the external light into the same colors as those of the corresponding pixels. In this case, the external light may not be visually recognized by the user. However, the present disclosure is not limited thereto, and the reflection preventing layer RPL may include, for example, a phase retarder and/or a polarizer to reduce the reflectance of the external light.

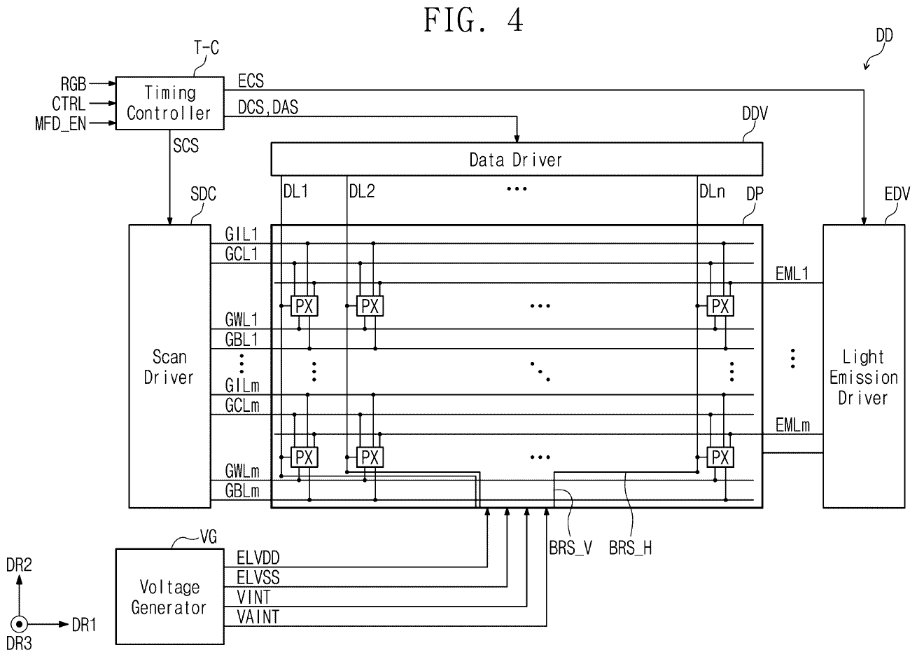

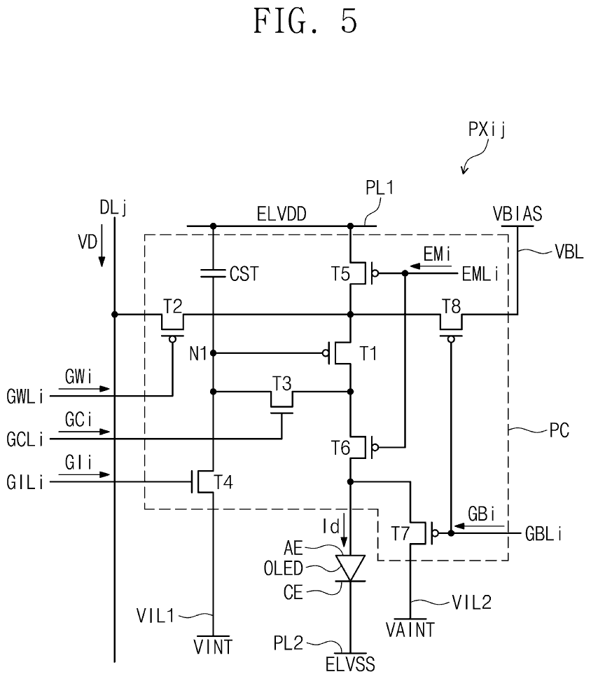

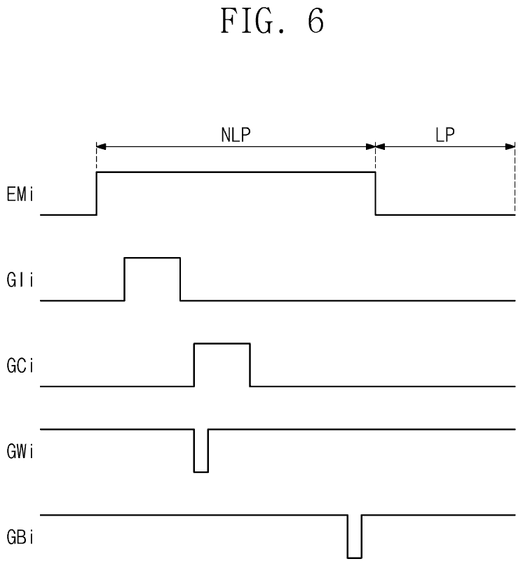

The electronic device DD according to an embodiment may further include a camera module. The camera module may be disposed under the display panel DP overlapping the display area DA. A pixel circuit PC (see FIG. 5) included in a pixel PX (see FIG. 4) overlapping the camera module and a pixel circuit PC (see FIG. 5) included in a pixel PX (see FIG. 4) not overlapping the camera module may have a lamination structure of conductive layers, which will be described later, but are not limited to an embodiment.

The window WIN may be disposed on the reflection preventing layer RPL. The window WIN may protect the display panel DP, the input sensing unit ISP, and the reflection preventing layer RPL from, for example, an external scratch and an impact.

The panel protecting film PPF may be disposed under the display panel DP.

The panel protecting film PPF may protect a lower portion of the display panel DP. The panel protecting film PPF may include a flexible plastic material such as polyethyleneterephthalate (PET).

The first adhesive layer AL1 may be disposed between the display panel DP and the panel protecting film PPF, and the display panel DP and the panel protecting film PPF may adhere to each other by using the first adhesive layer AL1. The second adhesive layer AL2 may be disposed between the window WIN and the reflection preventing layer RPL, and the window WIN and the reflection preventing layer RPL may adhere to each other by using the second adhesive layer AL2.

FIG. 3 is a view illustrating an example cross section of a display panel illustrated in FIG. 2.

As an example, FIG. 3 illustrates a cross section of the display panel DP when viewed in the second direction DR2.

Referring to FIG. 3, the display panel DP may include a substrate SUB, a circuit element layer DP-CL disposed on the substrate SUB, a display element layer DP-OLED disposed on the circuit element layer DP-CL, and a thin film encapsulation layer TFE disposed on the display element layer DP-OLED.

The substrate SUB may include the display area DA and the non-display area NDA around the display area DA. The substrate SUB may include glass or a flexible plastic material such as polyimide (PI). The display element layer DP-OLED may be disposed on the display area DA.

A plurality of pixels may be arranged in the circuit element layer DP-CL and the display element layer DP-OLED. Each of the pixels may include a transistor disposed on the circuit element layer DP-CL and a light emitting element disposed on the display element layer DP-OLED and connected to the transistor.

The thin film encapsulation layer TFE may be disposed on the circuit element layer DP-CL to cover the display element layer DP-OLED. The thin film encapsulation layer TFE may protect the pixels from moisture, oxygen, and/or an external foreign substance.

FIG. 4 is a block diagram of the electronic device illustrated in FIG. 1.

Referring to FIG. 4, the electronic device DD may include the display panel DP, a timing controller T-C, a scan driver SDV, a data driver DDV, a light emission driver EDV, and a voltage generator VG.

The display panel DP may include a plurality of scan lines GIL1 to GILm, GCL1 to GCLm, GWL1 to GWLm, and GBL1 to GBLm, a plurality of light emitting lines EML1 to EMLm, a plurality of data lines DL1 to DLn, and a plurality of pixels PX. “m” and “n” are natural numbers.

The plurality of pixels PX may be electrically connected to the plurality of scan lines GIL1 to GILm, GCL1 to GCLm, GWL1 to GWLm, and GBL1 to GBLm, the light emitting lines EML1 to EMLm, and the data lines DL1 to DLn. Each of the plurality of pixels PX may be electrically connected to corresponding four scan lines, one corresponding data line, and one corresponding light emitting line.

The plurality of scan lines GIL1 to GILm, GCL1 to GCLm, GWL1 to GWLm, and GBL1 to GBLm may include a plurality of initialization scan lines GIL1 to GILm, a plurality of compensation scan lines GCL1 to GCLm, a plurality of writing scan lines GWL1 to GWLm, and a plurality of bias scan lines GBL1 to GBLm.

Each of the plurality of pixels PX may be connected to a corresponding one of the plurality of initialization scan lines GIL1 to GILm, a corresponding one of the plurality of compensation scan lines GCL1 to GCLm, a corresponding one of the plurality of writing scan lines GWL1 to GWLm, and a corresponding one of the plurality of bias scan lines GBL1 to GBLm.

The plurality of scan lines GIL1 to GILm, GCL1 to GCLm, GWL1 to GWLm, and GBL1 to GBLm may be connected to the scan driver SDV, may extend in the first direction DR1, and may be arranged in the second direction DR2. The plurality of light emitting lines EML1 to EMLm may be connected to the light emission driver EDV, may extend in the first direction DR1, and may be arranged in the second direction DR2. The plurality of data lines DL1 to DLn may be connected to the data driver DDV, may extend in the second direction DR2, and may be arranged in the first direction DR1.

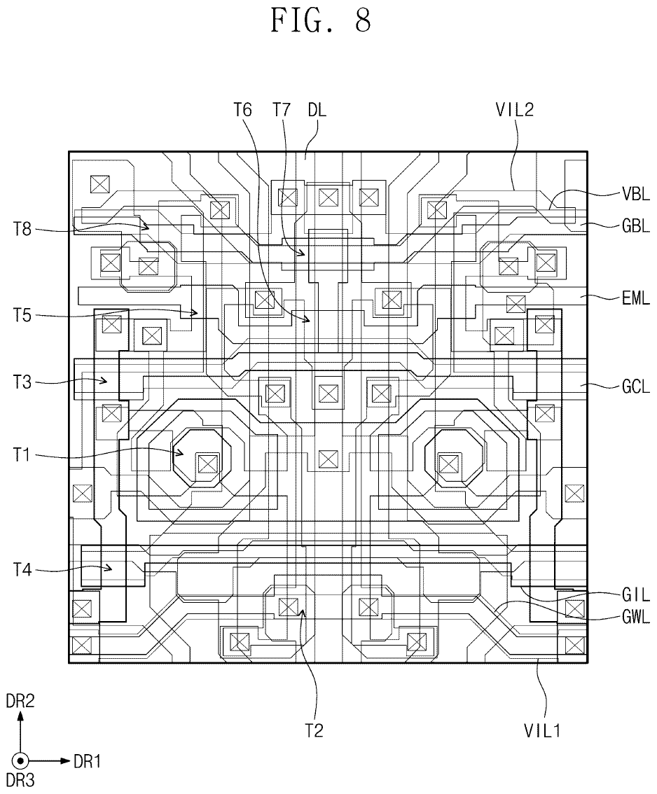

The scan driver SDV, the light emission driver EDV, and the data driver DDV may be substantially disposed on the display panel DP, and these components will be described in more detail later with reference to FIG. 8.

The timing controller T-C may receive an image signal RGB and a control signal CTRL. The timing controller T-C may generate an image data signal DAS obtained by converting a data format of the image signal RGB to satisfy an interface specification with respect to the data driver DDV. The timing controller T-C may output a scan control signal SCS, a data control signal DCS, and a light emitting control signal ECS based on the control signal CTRL.

The voltage generator VG may generate voltages required for operating the display panel DP. The voltage generator VG may generate a first driving voltage ELVDD, a second driving voltage ELVSS, a first initialization voltage VINT, and a second initialization voltage VAINT. The first driving voltage ELVDD, the second driving voltage ELVSS, the first initialization voltage VINT, and the second initialization voltage VAINT may be applied to the plurality of pixels PX.

The scan driver SDV may receive the scan control signal SCS from the timing controller T-C. The scan driver SDV may output scan signals to the plurality of scan lines GIL1 to GILm, GCL1 to GCLm, GWL1 to GWLm, and GBL1 to GBLm based on the scan control signal SCS. The scan signals may be applied to the plurality of pixels PX through the plurality of scan lines GIL1 to GILm, GCL1 to GCLm, GWL1 to GWLm, and GBL1 to GBLm.

The data driver DDV may receive the data control signal DCS and the image data signal DAS from the timing controller T-C. The data driver DDV may convert the image data signal DAS into data signals and output the converted data signals. The data signals may be defined as analog voltages corresponding to a grayscale level of the image data signal DAS. The data signals may be applied to the plurality of pixels PX through the data lines DL1 to DLn. FIG. 4 illustrates that the data driver DDV is disposed on an upper side of the display panel DP, but the present disclosure is not limited thereto. For example, the data driver DDV may be disposed at a lower end portion of the non-display area NDA of the display panel DP to be adjacent to pads included in the display panel DP.

The display panel DP according to an embodiment may include a first sub-line BRS_H and a second sub-line BRS_V. The first sub-line BRS_H may extend in the first direction DR1 and may be disposed inside the display area DA of the display panel DP. A first end portion of the first sub-line BRS_H may be connected to the second sub-line BRS_V, and a second end portion of the first sub-line BRS_H may be connected to the data line.

The second sub-line BRS_V may extend in the second direction DR2. A first end portion of the second sub-line BRS_V may be connected to the first end portion of the first sub-line BRS_H, and a second end portion of the second sub-line BRS_V may extend to the non-display area NDA and may be connected to the data driver DDV disposed at a lower end portion of the display panel DP.

According to an embodiment, in the display panel DP, the first sub-line BRS_H and the second sub-line BRS_V may be arranged inside the display panel DP, and thus an unnecessary dead space for arranging the data lines DL1 to DLn in the non-display area NDA may be reduced. Accordingly, the display panel DP in which the non-display area NDA is reduced may be provided.

The light emission driver EDV may receive the light emitting control signal ECS from the timing controller T-C. The light emission driver EDV may output light emitting signals to the light emitting lines EML1 to EMLm based on the light emitting control signal ECS. The light emitting signals may be applied to the plurality of pixels PX through the light emitting lines EML1 to EMLm.

The plurality of pixels PX may receive data voltages based on the scan signals. The plurality of pixels PX may display an image by emitting lights having brightness corresponding to the data voltages based on the light emitting signals.

FIG. 5 is a view illustrating an equivalent circuit of any one pixel among pixels illustrated in FIG. 4.

As an example, FIG. 5 illustrates a pixel PXij connected to a j^{th} data line DLj, i^{th} scan lines GWLi, GCLi, GILi, and GBLi, and a i^{th} light emitting line EMLi. “i” and “j” are natural numbers.

Referring to FIG. 5, the pixel PXij may include the pixel circuit PC and a light emitting element OLED connected to the pixel circuit PC. The pixel circuit PC may drive the light emitting element OLED.

The pixel circuit PC may include a plurality of transistors T1 to T8 and a capacitor CST. The transistors T1 to T8 and the capacitor CST may control an amount of a current flowing through the light emitting element OLED. The light emitting element OLED may generate a light having predetermined brightness according to the amount of the current provided thereto.

The i^{th} writing scan line GWLi may receive an i^{th} writing scan signal GWi, and the i^{th} compensation scan line GCLi may receive an i^{th} compensation scan signal GCi. The i^{th} initialization scan line GILi may receive an i^{th} initialization scan signal GIi, and the i^{th} bias scan line GBLi may receive an i^{th} bias scan signal GBi. The i^{th} light emitting line EMLi may receive an i^{th} light emitting signal EMi.

The pixel PXij may be connected to the j^{th} data line DLj, the i^{th} writing scan line GWLi, the i^{th} compensation scan line GCLi, the i^{th} initialization scan line GILi, the i^{th} bias scan line GBLi, the i^{th} light emitting line EMLi, a first initialization line VIL1, a second initialization line VIL2, a bias line VBL, a first power line PL1, and a second power line PL2.

The first initialization line VIL1 may receive the first initialization voltage VINT, and the second initialization line VIL2 may receive the second initialization voltage VAINT. The bias line VBL may receive a bias voltage VBIAS. The first power line PL1 may receive the first driving voltage ELVDD, and the second power line PL2 may receive the second driving voltage ELVSS.

Each of the transistors T1 to T8 may include a source electrode, a drain electrode, and a gate electrode. Hereinafter, in FIG. 5, for convenience, one of the source electrode and the drain electrode is defined as a first electrode, and the other thereof is defined as a second electrode. Further, the gate electrode is defined as a control electrode.

The transistors T1 to T8 may include the first to eighth transistors T1 to T8. The first, second, and fifth to eighth transistors T1, T2, and T5 to T8 may be p-type metal oxide semiconductor (PMOS) transistors. The third transistor T3 and the fourth transistor T4 may be n-type metal oxide semiconductor (NMOS) transistors.

The first transistor T1 may be defined as a “driving transistor,” and the second transistor T2 may be defined as a “switching transistor.” The third transistor T3 may be defined as a “compensation transistor.” The fourth transistor T4 may be defined as a “first initialization transistor” and the seventh transistor T7 may be defined as a “second initialization transistor.” The fifth transistor T5 may be defined as a “first light emitting control transistor” and the sixth transistor T6 may be defined as a “second light emitting control transistor.” The eighth transistor T8 may be defined as a “bias transistor.”

The light emitting element OLED may include an organic light emitting element. The light emitting element OLED may include a first electrode AE and a second electrode CE. The first electrode AE may receive the first driving voltage ELVDD through the sixth transistor T6, the first transistor T1, and the fifth transistor T5. The first driving voltage ELVDD may be applied to the pixel circuit PC through the first power line PL1.

The second electrode CE may receive the second driving voltage ELVSS having a lower level than that of the first driving voltage ELVDD. The second driving voltage ELVSS may be applied to the pixel circuit PC through the second power line PL2.

The first transistor T1 may be disposed between the fifth transistor T5 and the sixth transistor T6 and connected to the fifth transistor T5 and the sixth transistor T6. The first transistor T1 may be connected to the first power line PL1 through the fifth transistor T5, and may be connected to the first electrode AE through the sixth transistor T6.

The first transistor T1 may include a first electrode connected to the first power line PL1 through the fifth transistor T5, a second electrode connected to the first electrode AE through the sixth transistor T6, and a control electrode connected to a first node N1.

The first electrode of the first transistor T1 may be connected to the fifth transistor T5, and the second electrode of the first transistor T1 may be connected to the sixth transistor T6. The first transistor T1 may control the amount of current flowing through the light emitting element OLED according to a voltage of the first node N1 applied to the control electrode of the first transistor T1.

The second transistor T2 may be disposed between the first transistor T1 and the j^{th} data line DLj and connected to the first transistor T1 and the j^{th} data line DLj. The second transistor T2 may include a first electrode connected to the j^{th} data line DLj, a second electrode connected to the first electrode of the first transistor T1, and a control electrode connected to the i^{th} writing scan line GWLi.

The second transistor T2 may be turned on by the i^{th} writing scan signal GWi applied through the i^{th} writing scan line GWLi and electrically connect the j^{th} data line DLj and the first electrode of the first transistor T1. The second transistor T2 may perform a switching operation of providing a data voltage VD (corresponding to the above-described data signal) applied through the j^{th} data line DLj to the first electrode of the first transistor T1.

The third transistor T3 may be connected to the second electrode of the first transistor T1 and the first node N1. The third transistor T3 may include a first electrode connected to the second electrode of the first transistor T1, a second electrode connected to the first node N1, and a control electrode connected to the i^{th} compensation scan line GCLi.

The third transistor T3 may be turned on by the i^{th} compensation scan signal GCi applied through the i^{th} compensation scan line GCLi and electrically connect the second electrode of the first transistor T1 and the control electrode of the first transistor T1. When the third transistor T3 is turned on, the first transistor T1 and the third transistor T3 may be connected to each other in a form of a diode.

The fourth transistor T4 may be connected to the first node N1. The fourth transistor T4 may include a first electrode connected to the first node N1, a second electrode connected to the first initialization line VIL1, and a control electrode connected to the i^{th} initialization scan line GILi. The fourth transistor T4 may be turned on by the i^{th} initialization scan signal GIi applied through the i^{th} initialization scan line GILi and provide the first initialization voltage VINT applied through the first initialization line VIL1 to the first node N1.

The fifth transistor T5 may include a first electrode connected to the first power line PL1, a second electrode connected to the first electrode of the first transistor T1, and a control electrode connected to the i^{th} light emitting line EMLi.

The sixth transistor T6 may include a first electrode connected to the second electrode of the first transistor T1, a second electrode connected to the first electrode AE, and a control electrode connected to the i^{th} light emitting line EMLi.

The fifth transistor T5 and the sixth transistor T6 may be turned on by the i^{th} light emitting signal EMi applied through the i^{th} light emitting line EMLi. The first driving voltage ELVDD may be provided to the light emitting element OLED by the turned-on fifth transistor T5 and the turned-on sixth transistor T6, such that that a driving current may flow in the light emitting element OLED. Thus, the light emitting element OLED may emit a light.

The seventh transistor T7 may include a first electrode connected to the first electrode AE, a second electrode connected to the second initialization line VIL2, and a control electrode connected to the i^{th} bias scan line GBLi. The seventh transistor T7 may be turned on by the i^{th} bias scan signal GBi applied through the i^{th} bias scan line GBLi and provide the second initialization voltage VAINT received through the second initialization line VIL2 to the first electrode AE of the light emitting element OLED.

In an embodiment of the present disclosure, the second initialization voltage VAINT may have a different level from the first initialization voltage VINT, but the present disclosure is not limited thereto, and the second initialization voltage VAINT may have the same level as that first initialization voltage VINT.

The seventh transistor T7 may improve black expression capability of the pixel PXij. When the seventh transistor T7 is turned on, a parasitic capacitor (not illustrated) of the light emitting element OLED may be discharged. Thus, when black brightness is implemented, the light emitting element OLED does not emit a light due to a leakage current of the first transistor T1, and accordingly, the black expression capability may be improved.

The capacitor CST may include a first electrode connected to the first power line PL1 and a second electrode connected to the first node N1. When the fifth transistor T5 and the sixth transistor T6 are turned on, the amount of current flowing through the first transistor T1 may be determined according to a voltage stored in the capacitor CST.

The eighth transistor T8 may include a first electrode connected to the bias line VBL, a second electrode connected to the first electrode of the first transistor T1, and a control electrode connected to the i^{th} bias scan line GBLi.

The eighth transistor T8 may be turned on by the i^{th} bias scan signal GBi and provide the bias voltage VBIAS applied through the bias line VBL to the first electrode of the first transistor T1.

FIG. 6 is a timing diagram of scan signals and light emitting signals for describing an operation of the pixel illustrated in FIG. 5.

Referring to FIGS. 5 and 6, the i^{th} light emitting signal EMi may have a high level during a non-light emitting period NLP and have a low level during a light emitting period LP.

An activation period of each of the i^{th} writing scan signal GWi and the i^{th} bias scan signal GBi may be defined as a low level of each of the i^{th} writing scan signal GWi and the i^{th} bias scan signal GBi.

An activation period of each of the i^{th} compensation scan signal GCi and the i^{th} initialization scan signal GIi may be defined as a high level of each of the i^{th} compensation scan signal GCi and the i^{th} initialization scan signal GIi.

After the i^{th} initialization scan signal GIi is activated, the i^{th} compensation scan signal GCi and the i^{th} writing scan signal GWi may be activated. Thereafter, the i^{th} bias scan signal GBi may be activated.

During the non-light emitting period NLP, the i^{th} initialization scan signal GIi, the i^{th} compensation scan signal GCi, the i^{th} writing scan signal GWi, and the i^{th} bias scan signal GBi that are activated may be applied to the pixel PXij.

The i^{th} initialization scan signal GIi may be applied to the fourth transistor T4 to turn on the fourth transistor T4. The first initialization voltage VINT may be provided to the first node N1 through the fourth transistor T4. Thus, the first initialization voltage VINT may be applied to the control electrode of the first transistor T1, and the first transistor T1 may be initialized by the first initialization voltage VINT. This operation may be defined as an initialization operation.

The i^{th} writing scan signal GWi may be applied to the second transistor T2 to turn on the second transistor T2. Further, the i^{th} compensation scan signal GCi may be applied to the third transistor T3 to turn on the third transistor T3.

The first transistor T1 and the third transistor T3 may be connected to each other in the form of a diode. In this case, a compensation voltage VD-Vth obtained by subtracting a threshold voltage Vth of the first transistor T1 from the data voltage VD supplied through the data line DLj may be applied to the control electrode of the first transistor T1. This operation may be defined as a writing operation (or a programming operation) and a compensation operation.

The first driving voltage ELVDD and the compensation voltage VD-Vth may be respectively applied to the first electrode and the second electrode of the capacitor CST. A charge corresponding to a difference between a voltage of the first electrode of the capacitor CST and a voltage of the second electrode of the capacitor CST may be stored in the capacitor CST.

Thereafter, the i^{th} bias scan signal GBi may be applied to the seventh transistor T7 and the eighth transistor T8 to turn on the seventh transistor T7 and the eighth transistor T8. The second initialization voltage VAINT may be provided to the first electrode AE of the light emitting element OLED through the seventh transistor T7 such that the first electrode AE is initialized by the second initialization voltage VAINT. The bias voltage VBIAS may be applied to the first electrode of the first transistor T1 through the eighth transistor T8.

During the light emitting period LP, the i^{th} light emitting signal EMi may be applied to the fifth transistor T5 and the sixth transistor T6 through the i^{th} light emitting line EMLi to turn on the fifth transistor T5 and the sixth transistor T6. Accordingly, a driving current Id corresponding to a difference between a voltage of the control electrode of the first transistor T1 and the first driving voltage ELVDD may be generated. The driving current Id may be provided to the light emitting element OLED through the sixth transistor T6 such that the light emitting element OLED emits a light.

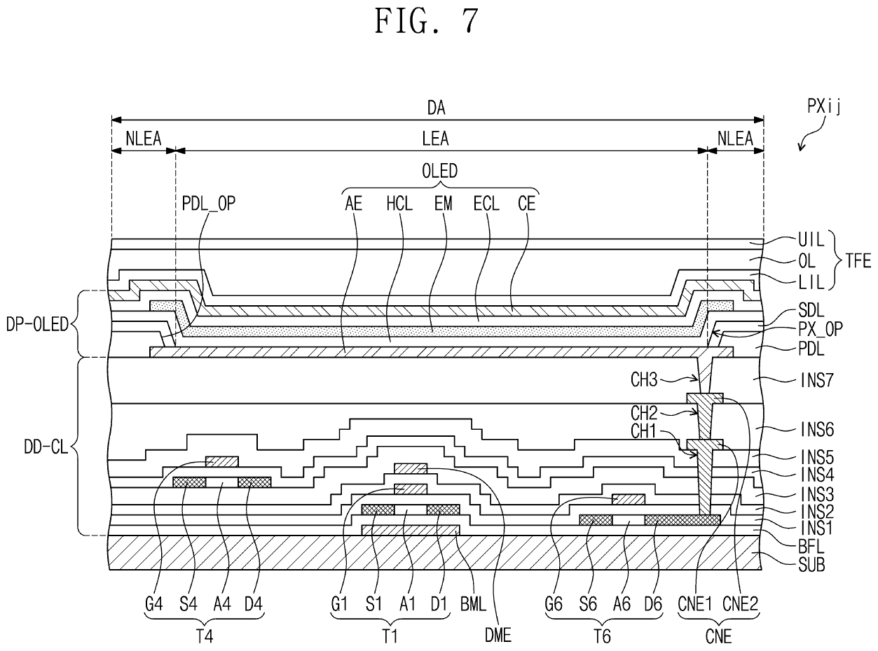

FIG. 7 is a view illustrating an example cross section including a light emitting element, a first transistor, a fourth transistor, and a sixth transistor of the pixel illustrated in FIG. 5.

Referring to FIG. 7, the light emitting element OLED may include the first electrode AE, the second electrode CE, a hole control layer HCL, an electron control layer ECL, and a light emitting layer EM. The first electrode AE may correspond to the first electrode AE illustrated in FIG. 5, and the second electrode CE may correspond to the second electrode CE illustrated in FIG. 5. The second electrode CE may be disposed above the first electrode AE, and the hole control layer HCL, the electron control layer ECL, and the light emitting layer EM may be disposed between the first electrode AE and the second electrode CE.

The first transistor T1, the fourth transistor T4, the sixth transistor T6, and the light emitting element OLED may be disposed on the substrate SUB. The display area DA may include a light emitting area LEA corresponding to the pixel PXij and a non-light emitting area NLEA adjacent to the light emitting area LEA. The light emitting element OLED may be disposed in the light emitting area LEA.

A lower metal layer BML may be disposed on the substrate SUB. The lower metal layer BML may overlap the first transistor T1. Although not illustrated, a constant voltage may be applied to the lower metal layer BML. When the constant voltage is applied to the lower metal layer BML, the threshold voltage Vth of the first transistor T1 disposed on the lower metal layer BML may be maintained without changing.

The lower metal layer BML may block a light incident to the first transistor T1 from a lower side of the lower metal layer BML. The lower metal layer BML may include a reflective metal. the lower metal layer BML may be omitted in an embodiment.

A buffer layer BFL may be disposed on the substrate SUB, and the buffer layer BFL may be an inorganic layer. The buffer layer BFL may cover the lower metal layer BML. According to an embodiment, a barrier layer disposed between the buffer layer BFL and the substrate SUB may be further included. The barrier layer may include an inorganic material.

Semiconductor layers S1, A1, and D1 of the first transistor T1 and semiconductor layers S6, A6, and D6 of the sixth transistor T6 may be disposed on the buffer layer BFL. The semiconductor layers S1, A1, D1, S6, A6, and D6 may include polysilicon. However, the present disclosure is not limited thereto, and the semiconductor layers S1, A1, D1, S6, A6, and D6 may include amorphous silicon.

The semiconductor layers S1, A1, D1, S6, A6, and D6 may be doped with N-type dopants or P-type dopants. The semiconductor layers S1, A1, D1, S6, A6, and D6 may include a high doped area and a low doped area. The high doped area may have conductivity that is greater than conductivity of the low doped area and substantially serve as source electrodes and drain electrodes of the first transistor T1 and the sixth transistor T6. The low-doped areas may substantially correspond to active areas (or channels) of the first transistor T1 and the sixth transistor T6.

A first source area S1, a first channel area A1, and a first drain area D1 of the first transistor T1 may be formed from the semiconductor layers S1, A1, and D1. A sixth source area S6, a sixth channel area A6, and a sixth drain area D6 of the sixth transistor T6 may be formed from the semiconductor layers S6, A6, and D6. The first channel area A1 may be disposed between the first source area S1 and the first drain area D1. The sixth channel area A6 may be disposed between the sixth source area S6 and the sixth drain area D6.

A first insulating layer INS1 may be disposed on the buffer layer BFL to cover the semiconductor layers S1, A1, D1, S6, A6, and D6. A first gate electrode G1 (or a control electrode) of the first transistor T1 and a sixth gate electrode G6 (or a control electrode) of the sixth transistors T6 may be disposed on the first insulating layer INS1. When viewed on a plane (e.g., defined by the first direction DR1 and the second direction DR2), the first gate electrode G1 may overlap the first channel area A1, and the sixth gate electrode G6 may overlap the sixth channel area A6.

Although not illustrated, structures of a source area, a channel area, a drain area, and a gate electrode of each of the second transistor T2, the fifth transistor T5, and the seventh transistor T7 may be substantially the same as those of the first transistor T1 and the sixth transistor T6.

A second insulating layer INS2 may be disposed on the first insulating layer INS1 to cover the first gate electrode G1 and the sixth gate electrode G6. A dummy electrode DME may be disposed on the second insulating layer INS2. The dummy electrode DME may be disposed on the first gate electrode G1 and may overlap the first gate electrode G1 when viewed on a plane. The dummy electrode DME may form the capacitor CST together with the first gate electrode G1.

A third insulating layer INS3 may be disposed on the second insulating layer INS2 to cover the dummy electrode DME. Semiconductor layers S4, A4, and D4 of the fourth transistor T4 may be disposed on the third insulating layer INS3. The semiconductor layers S4, A4, and D4 may include an oxide semiconductor including a metal oxide. The oxide semiconductor may include a crystalline or amorphous oxide semiconductor.

The semiconductor layers S4, A4, and D4 may include a plurality of areas that distinguish from each other depending on whether or not the metal oxide included therein is reduced. An area (hereinafter, referred to as a reduced area) in which the metal oxide is reduced has higher conductivity than that of an area (hereinafter, a non-reduced area) in which the metal oxide is not reduced. The reduced area may substantially serve as a source electrode or a drain electrode of the fourth transistor T4. The non-reduced area may substantially correspond to an active area (or a channel) of the fourth transistor T4.

A fourth source area S4, a fourth channel area A4, and a fourth drain area D4 of the fourth transistor T4 may be formed from the semiconductor layers S4, A4, and D4. The fourth channel area A4 may be disposed between the fourth source area S4 and the fourth drain area D4.

A fourth insulating layer INS4 may be disposed on the third insulating layer INS3 to cover the semiconductor layers S4, A4, and D4. A fourth gate electrode G4 of the fourth transistor T4 may be disposed on the fourth insulating layer INS4. When viewed on a plane, the fourth gate electrode G4 may overlap the fourth channel area A4.

A fifth insulating layer INS5 may be disposed on the fourth insulating layer INS4 to cover the fourth gate electrode G4. Although not illustrated, structures of a source area, a channel area, a drain area, and a gate electrode of the third transistor T3 may be substantially the same as those of the fourth transistor T4.

The buffer layer BFL and the first to fifth insulating layers INS1 to INS5 may include inorganic layers. For example, the buffer layer BFL, the first insulating layer INS1, and the fourth insulating layer INS4 may include a silicon oxide layer, and the second insulating layer INS2 may include a silicon nitride layer.

The third insulating layer INS3 and the fifth insulating layer INS5 may include a plurality of inorganic insulating layers including different materials and laminated on each other. For example, the third insulating layer INS3 may include a silicon nitride layer and a silicon oxide layer that are sequentially laminated, and the fifth insulating layer INS5 may include a silicon oxide layer and a silicon nitride layer that are sequentially laminated. A thickness of each of the third insulating layer INS3 and the fifth insulating layer INS5 may be greater than a thickness of each of the buffer layer BFL, the first insulating layer INS1, the second insulating layer INS2, and the fourth insulating layer INS4.

A connection electrode CNE may be disposed between the sixth transistor T6 and the light emitting element OLED. The connection electrode CNE may electrically connect the sixth transistor T6 and the light emitting element OLED. The connection electrode CNE may include a first connection electrode CNE1 and a second connection electrode CNE2 disposed on the first connection electrode CNE1.

The first connection electrode CNE1 may be disposed on the fifth insulating layer INS5 and may be connected to the sixth drain area D6 through a first contact hole CH1 defined by the first to fifth insulating layers INS1 to INS5. A sixth insulating layer INS6 may be disposed on the fifth insulating layer INS5 to cover the first connection electrode CNE1.

The second connection electrode CNE2 may be disposed on the sixth insulating layer INS6. The second connection electrode CNE2 may be connected to the first connection electrode CNE1 through a second contact hole CH2 defined by the sixth insulating layer INS6.

A seventh insulating layer INS7 may be disposed on the sixth insulating layer INS6 to cover the second connection electrode CNE2. The sixth insulating layer INS6 and the seventh insulating layer INS7 may include inorganic layers or organic layers.

The first electrode AE may be disposed on the seventh insulating layer INS7. The first electrode AE may be electrically connected to the second connection electrode CNE2 through a third contact hole CH3 defined by the seventh insulating layer INS7.

A pixel defining film PDL, through which a predetermined portion of the first electrode AE is exposed, may be disposed on the first electrode AE and the seventh insulating layer INS7. A first opening PDL_OP, through which the predetermined portion of the first electrode AE is exposed, may be defined in the pixel defining film PDL.

A spacer SDL may be disposed on the pixel defining film PDL. The spacer SDL may include an organic material and may support a mask used in a process of depositing the light emitting layer EM. A second opening PX_OP that overlaps the first opening PDL_OP may be defined in the spacer SDL.

The hole control layer HCL may be disposed on the first electrode AE and the spacer SDL. The hole control layer HCL may be commonly disposed in the light emitting area LEA and the non-light emitting area NLEA. The hole control layer HCL may include a hole transport layer and a hole injection layer.

The light emitting layer EM may be disposed on the hole control layer HCL. The light emitting layer EM may be disposed in an area corresponding to the second opening PX_OP. The light emitting layer EM may include an organic material and/or an inorganic material. The light emitting layer EM may generate a light corresponding to any one of red, green, and blue color.

The electron control layer ECL may be disposed on the light emitting layer EM and the hole control layer HCL. The electron control layer ECL may be commonly disposed in the light emitting area LEA and the non-light emitting area NLEA. The electron control layer ECL may include an electron transport layer and an electron injection layer.

The second electrode CE may be disposed on the electron control layer ECL. The second electrode CE may be commonly disposed in the plurality of pixels PX. That is, the second electrode CE may be commonly disposed on the light emitting layers EM of the plurality of pixels PX.

Layer from the buffer layer BFL to the seventh insulating layer INS7 may be defined as the circuit element layer DP-CL. A layer, on which the light emitting element OLED is disposed, may be defined as the display element layer DP-OLED.

The thin film encapsulation layer TFE may be disposed on the light emitting element OLED. The thin film encapsulation layer TFE may include a first inorganic layer LIL, an organic layer OL, and a second inorganic layer UIL that are sequentially laminated. The inorganic layers LIL and UIL may include inorganic materials and protect the plurality of pixels PX from moisture and/or oxygen. The organic layer OL may include an organic material and protect the plurality of pixels PX from a foreign substance such as a dust particle.

The first driving voltage ELVDD may be applied to the first electrode AE, and the second driving voltage ELVSS may be applied to the second electrode CE. Holes and electrons injected into the light emitting layer EM may be combined to each other to form excitons, and as the excitons transition to a ground state, the light emitting element OLED may emit a light. The light emitting element OLED may emit a light to display an image.

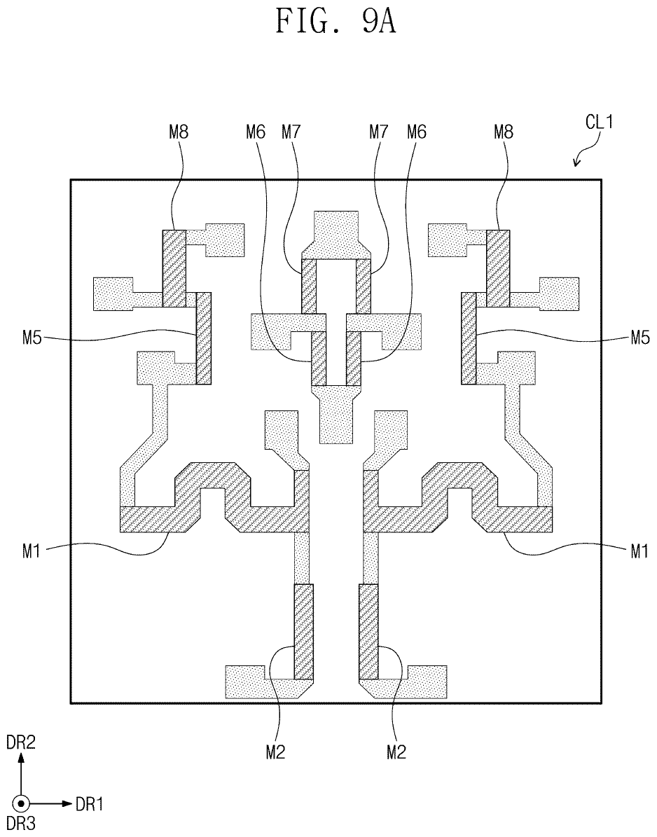

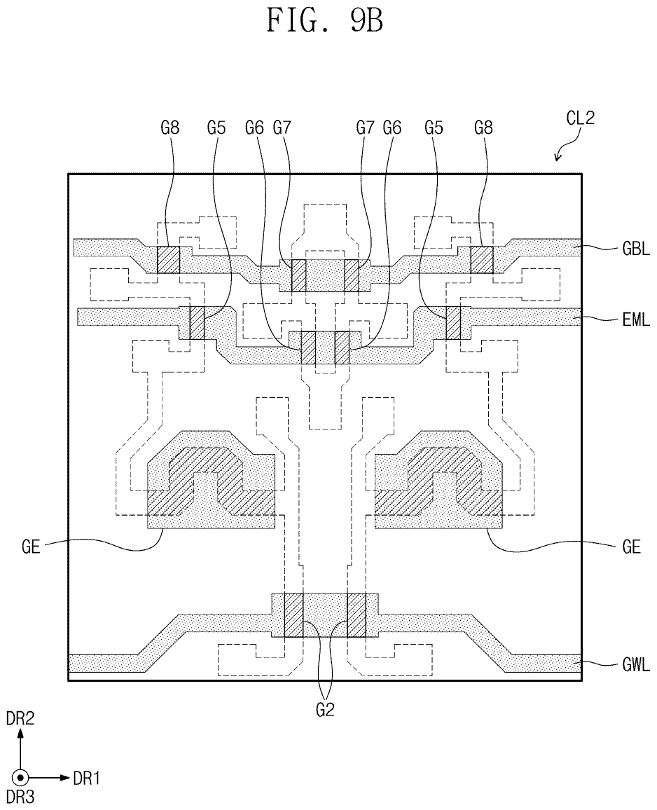

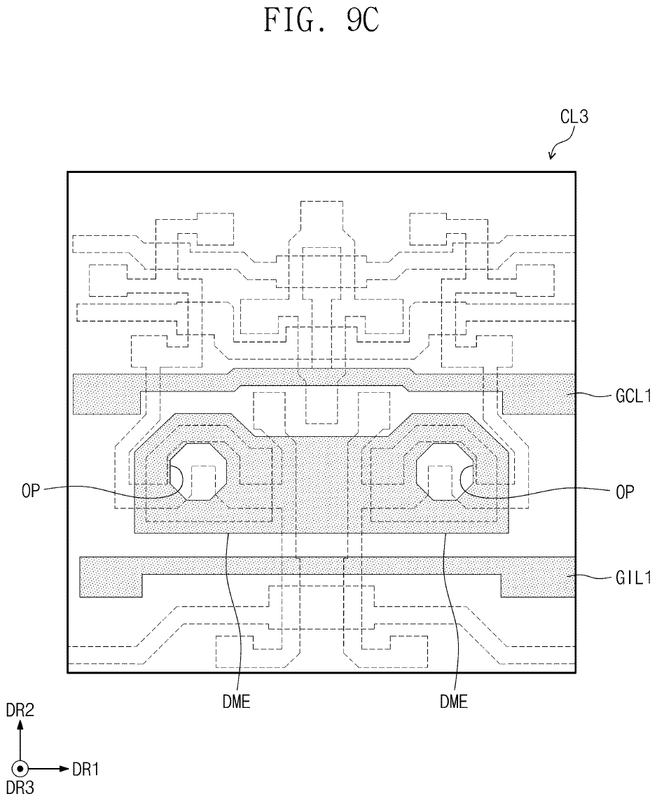

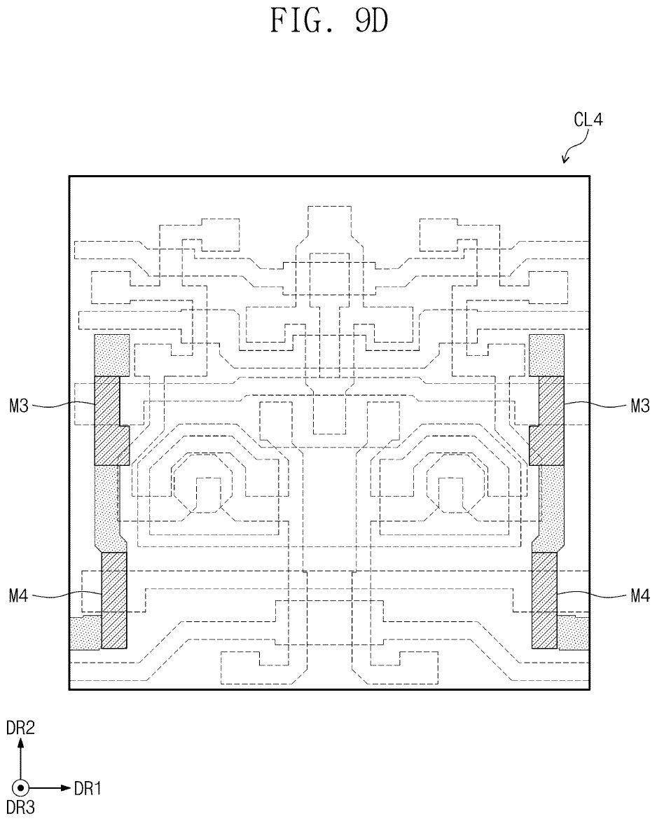

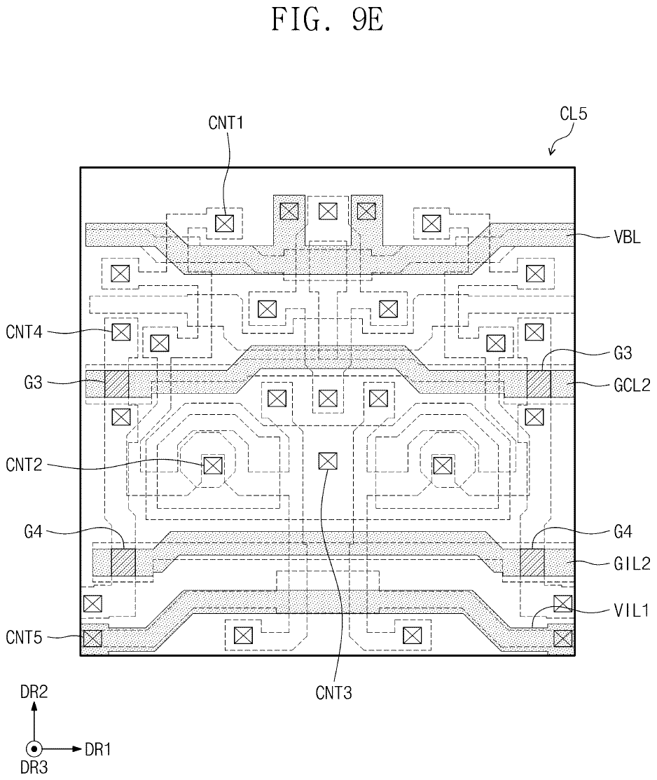

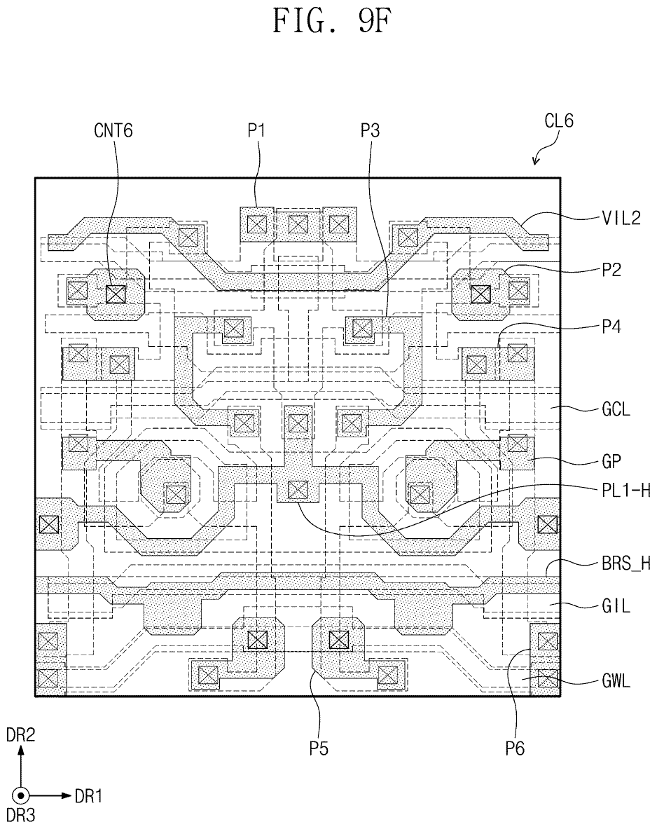

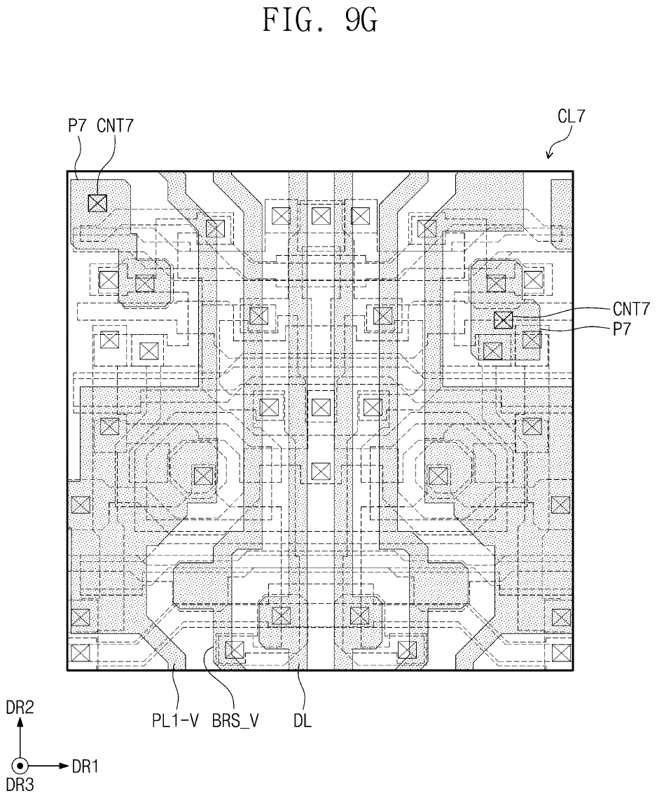

FIG. 8 is a plan view illustrating a lamination relationship of conductive layers included in a pixel circuit according to one or more embodiments of the present disclosure. FIGS. 9A to 9G are plan views illustrating conductive patterns included in the conductive layers of the pixel circuit according to one or more embodiments of the present disclosure. The same and/or similar reference numerals are used for the same and/or similar components as those described in FIGS. 1 to 7, and duplicated descriptions thereof will be omitted.

FIG. 8 illustrates two pixel circuits PC (see FIG. 5) included in two pixels PX adjacent to each other in the first direction DR1 among the plurality of pixels PX described in FIG. 4. Signal lines and conductive patterns included in the two pixel circuits PC (see FIG. 5) included in the two pixels PX adjacent to each other in the first direction DR1 may have a linear symmetrical shape with respect to an imaginary center line extending in the second direction DR2, a description related to the signal lines and the conductive patterns included in the one pixel circuit PC (see FIG. 5) may be equally applied to the adjacent pixel circuit PC (see FIG. 5), and a duplicated description thereof is omitted.

Referring to FIG. 8, the pixel PX (see FIG. 4) may include the first to eighth transistors T1 to T8. The pixel PX (see FIG. 4) may be connected to the signal lines. The signal lines may include a data line DL, a writing scan line GWL, a compensation scan line GCL, an initialization scan line GIL, a bias scan line GBL, a light emitting line EML, the first initialization line VIL1, the second initialization line VIL2, the bias line VBL, the first power line PL1 (see FIG. 4), and the second power line PL2 (see FIG. 4).

According to the present disclosure, among the signal lines arranged in the pixel circuit PC (see FIG. 5) on a plane, signal lines extending in the first direction DR1 may be arranged in a predetermined order in the second direction DR2. For example, the signal lines extending in the first direction DR1 may be arranged in the second direction DR2 from an upper portion of the pixel circuit PC (see FIG. 5) in an order of the second initialization line VIL2, the bias line VBL, the bias scan line GBL, the light emitting line EML, the compensation scan line GCL, the initialization scan line GIL, the writing scan line GWL, and the first initialization line VIL1. According to the present disclosure, the first transistor T1 (defined as the “driving transistor”) may be provided in a space between the compensation scan line GCL and the initialization scan line GIL while being spaced apart from the compensation scan line GCL and the initialization scan line GIL. Thus, an area and/or a width of the semiconductor layer A1 (see FIG. 9A) included in the first transistor T1 (driving transistor) may increase, and thus brightness of the display panel DP may increase.

Referring to FIGS. 8 and 9A, a first conductive layer CL1 may include semiconductor layers M1, M2, and M5 to M8. The first conductive layer CL1 may be disposed on the buffer layer BFL described in FIG. 7 and may be covered by the first insulating layer INS1. The semiconductor layers M1, M2, and M5 to M8 may include a first semiconductor layer M1 included in the first transistor T1, a second semiconductor layer M2 included in the second transistor T2, a fifth semiconductor layer M5 included in the fifth transistor T5, a sixth semiconductor layer M6 included in the sixth transistor T6, a seventh semiconductor layer M7 included in the seventh transistor T7, and an eighth semiconductor layer M8 included in the eighth transistor T8.

Each of the semiconductor layers M1, M2, and M5 to M8 included in the first conductive layer CL1 may include an active area (or a channel), a source electrode, and a drain electrode. According to the present disclosure, each of the semiconductor layers M1, M2, and M5 to M8 included in the first conductive layer CL1 may include polysilicon. However, the present disclosure is not limited thereto, and the semiconductor layers M1, M2, and M5 to M8 may include amorphous silicon.

Referring to FIGS. 8 and 9B, a second conductive layer CL2 may include the bias scan line GBL, the light emitting line EML, the writing scan line GWL, and an electrode pattern GE included in the first transistor T1. The second conductive layer CL2 may be disposed on the first insulating layer INS1 described in FIG. 7 and may be covered by the second insulating layer INS2.

The bias scan line GBL, the light emitting line EML, and the writing scan line GWL may extend in the first direction DR1 and may be spaced apart from each other in the second direction DR2. The electrode pattern GE may be disposed between the light emitting line EML and the writing scan line GWL.

A portion of the bias scan line GBL, which overlaps the first conductive layer CL1, may be defined as a “gate electrode” of a transistor. The portion of the bias scan line GBL may be defined as a gate electrode of the seventh transistor T7 and the eighth transistor T8. Thus, the eighth transistor T8 may be defined as the “bias transistor.” The seventh transistor T7 may be defined as the “second initialization transistor” by receiving the second initialization voltage VAINT from the second initialization line VIL2.

A portion of the light emitting line EML, which overlaps the first conductive layer CL1, may be defined as a “gate electrode” of a transistor. The portion of the light emitting line EML may be defined as a gate electrode of the fifth transistor T5 and the sixth transistor T6. Thus, the fifth transistor T5 may be defined as the “first light emitting control transistor” and the sixth transistor T6 may be defined as the “second light emitting control transistor.”

A portion of the writing scan line GWL, which overlaps the first conductive layer CL1, may be defined as a “gate electrode” of a transistor. The portion of the writing scan line GWL may be defined as a gate electrode of the second transistor T2. Thus, the second transistor T2 may be defined as the “switching transistor.”

A portion of the electrode pattern GE, which overlaps the first semiconductor layer M1 of the first transistor T1, may be defined as the first gate electrode G1 (see FIG. 7) of the first transistor T1. According to the present disclosure, the electrode pattern GE may be disposed between the light emitting line EML and the writing scan line GWL.

Referring to FIGS. 8 and 9C, a third conductive layer CL3 may include a lower layer GCL1 of the compensation scan line GCL, a lower layer GIL1 of the initialization scan line GIL, and the dummy electrode DME. The third conductive layer CL3 may be disposed on the second insulating layer INS2 described in FIG. 7 and may be covered by the third insulating layer INS3.

The lower layers GCL1 and GIL1 may extend in the first direction DR1 and may be spaced apart from each other in the second direction DR2. The dummy electrode DME may be disposed between the lower layers GCL1 and GIL1.

An opening OP, through which a portion of the electrode pattern GE defined as the first gate electrode G1 (see FIG. 7) is exposed, may be defined in the dummy electrode DME. A contact hole may be defined in the insulating layers overlapping the opening OP, and a gate pattern GP (see FIG. 9F), which will be described later, may be disposed in the contact hole and connected to the electrode pattern GE.

Referring to FIGS. 8 and 9D, a fourth conductive layer CL4 may include semiconductor layers M3 and M4. The semiconductor layers M3 and M4 may be substantially defined as different portions in one pattern. The fourth conductive layer CL4 may be disposed on the third insulating layer INS3 described in FIG. 7 and may be covered by the fourth insulating layer INS4.

The semiconductor layers M3 and M4 may include a third semiconductor layer M3 included in the third transistor T3 and a fourth semiconductor layer M4 included in the fourth transistor T4.

Each of the semiconductor layers M3 and M4 included in the fourth conductive layer CL4 may include an active area (or a channel), a source electrode, and a drain electrode. According to the present disclosure, each of the semiconductor layers M3 and M4 included in the fourth conductive layer CL4 may include a metal oxide.

Referring to FIGS. 8 and 9E, a fifth conductive layer CL5 may include the bias line VBL, an upper layer GCL2 of the compensation scan line GCL, an upper layer GIL2 of the initialization scan line GIL, and the first initialization line VIL1. The fifth conductive layer CL5 may be disposed on the fourth insulating layer INS4 described in FIG. 7 and may be covered by the fifth insulating layer INS5.

The bias line VBL, the upper layer GCL2 of the compensation scan line GCL, the upper layer GIL2 of the initialization scan line GIL, and the first initialization line VIL1 may extend in the first direction DR1 and may be spaced apart from each other in the second direction DR2.

According to an embodiment, at least a portion of the first initialization line VIL1 may overlap the writing scan line GWL included in the second conductive layer CL2.

A portion of the upper layer GCL2 of the compensation scan line GCL, which overlaps the fourth conductive layer CL4, may be defined as a “gate electrode” of a transistor. The portion of the upper layer GCL2 may be defined as a gate electrode of the third transistor T3. Thus, the third transistor T3 may be defined as the “compensation transistor.”

A portion of the upper layer GIL2 of the initialization scan line GIL, which overlaps the fourth conductive layer CL4, may be defined as a “gate electrode” of a transistor. The portion of the upper layer GIL2 may be defined as a gate electrode of the fourth transistor T4. Thus, the fourth transistor T4 may be defined as the “first initialization transistor.”

FIG. 9E illustrates contact holes CNT1 to CNT5 that penetrate at least one of the first to fifth insulating layers INS1 to INS5 described in FIG. 7.

A first contact hole CNT1 may penetrate the first to fifth insulating layers INS1 to INS5 to expose the conductive patterns included in the first conductive layer CL1.

A second contact hole CNT2 may penetrate the second insulating layer INS2, the third insulating layer INS3, the fourth insulating layer INS4, and the fifth insulating layer INS5 to expose the conductive patterns included in the second conductive layer CL2.

A third contact hole CNT3 may penetrate the third insulating layer INS3, the fourth insulating layer INS4, and the fifth insulating layer INS5 to expose the conductive patterns included in the third conductive layer CL3.

A fourth contact hole CNT4 may penetrate the fourth insulating layer INS4 and the fifth insulating layer INS5 to expose the conductive patterns included in the fourth conductive layer CL4.

A fifth contact hole CNT5 may penetrate the fifth insulating layer INS5 to expose the conductive patterns included in the fifth conductive layer CL5.

Referring to FIGS. 8 and 9F, a sixth conductive layer CL6 may include first to sixth patterns P1 to P6, the second initialization line VIL2, the gate pattern GP, a lower line PL1-H of the first power line PL1, and the first sub-line BRS_H. The sixth conductive layer CL6 may be disposed on the fifth insulating layer INS5 described in FIG. 7 and may be covered by the sixth insulating layer INS6.

FIG. 9F illustrates a sixth contact hole CNT6 penetrating the sixth insulating layer INS6 described in FIG. 7. The sixth contact hole CNT6 may penetrate the sixth insulating layer INS6 to expose the conductive patterns included in the sixth conductive layer CL6. The sixth contact hole CNT6 may overlap the second pattern P2, the lower line PL1-H, and the fifth pattern P5.

A central portion of the first pattern P1 may be connected to a portion of the first conductive layer CL1, which protrudes from the seventh semiconductor layer M7, through the first contact hole CNT1. Further, an end portion of the first pattern P1 may be connected to the bias line VBL through the fifth contact hole CNT5.

One end portion of the second pattern P2 may be connected to a portion of the first conductive layer CL1, which protrudes from the eighth semiconductor layer M8, through the first contact hole CNT1.

One end portion of the third pattern P3 may be connected to a portion of the first conductive layer CL1, which protrudes between the sixth semiconductor layer M6 and the seventh semiconductor layer M7, through the first contact hole CNT1. An opposite end portion of the third pattern P3 may be connected to a portion of the first conductive layer CL1, which protrudes from the first semiconductor layer M1.

One end portion of the fourth pattern P4 may be connected to a portion of the first conductive layer CL1, which protrudes from the fifth semiconductor layer M5, through the first contact hole CNT1. An opposite end portion of the fourth pattern P4 may be connected to a portion of the fourth conductive layer CL4, which protrudes from the third semiconductor layer M3, through the fourth contact hole CNT4.

One end portion of the fifth pattern P5 may be connected to a portion of the first conductive layer CL1, which protrudes from the second semiconductor layer M2, through the first contact hole CNT1.

One end portion of the sixth pattern P6 may be connected to a portion of the fourth conductive layer CL4, which protrudes from the fourth semiconductor layer M4, through the fourth contact hole CNT4. An opposite end portion of the sixth pattern P6 may be connected to the first initialization line VIL1 through the fifth contact hole CNT5.

The second initialization line VIL2 may be connected to a portion of the first conductive layer CL1, which protrudes from the eighth semiconductor layer M8, through the first contact hole CNT1. According to an embodiment, a portion of the second initialization line VIL2 may overlap the bias line VBL, and the other portion of the second initialization line VIL2 may protrude upward in the second direction DR2 further than the bias line VBL and may be disposed above the bias line VBL on a plan view.

One end portion of the gate pattern GP may be connected to the electrode pattern GE through the second contact hole CNT2 overlapping the opening OP. An opposite end portion of the gate pattern GP may be connected to the portion of the fourth conductive layer CL4, which protrudes from the third semiconductor layer M3, through the fourth contact hole CNT4.

In an embodiment, the gate pattern GP may be disposed on the same layer as the second initialization line VIL2. The gate pattern GP may not overlap the compensation scan line GCL, the initialization scan line GIL, the writing scan line GWL, and the bias scan line GBL on a plane. The gate pattern GP may correspond to the first node N1 described in FIG. 5.

According to an embodiment, as the gate pattern GP is disposed not to overlap the writing scan line GWL, the compensation scan line GCL, and the initialization scan line GIL, the gate pattern GP may overlap the writing scan line GWL and the initialization scan line GIL, and thus a number of a contact hole for connection to a bridge pattern to pass therethrough may be reduced. Accordingly, heat may be transferred by the contact hole during an annealing process for forming the first transistor T1 to prevent thermal deformation, and the plurality of pixels PX (see FIG. 4) including the first transistor T1 having reduced hysteresis may be provided. A parasitic cap between the gate pattern GP and the writing scan line GWL may be reduced, and thus the display panel DP having improved brightness may be provided.

A portion of the lower line PL1-H of the first power line PL1, which is disposed between the third patterns P3, may be connected to a portion of the first conductive layer CL1, which protrudes from the seventh semiconductor layer M7, through the first contact hole CNT1.

A portion of the lower line PL1-H of the first power line PL1, which is disposed between the gate patterns GP, may be connected to the dummy electrode DME through the third contact hole CNT3.

The first sub-line BRS_H may be connected to the data line DL, which will be described with reference to FIG. 9G. As described above, when some of the data lines DL1 to DLn described in FIG. 4 are arranged in the display area DA to reduce the non-display area NDA described in FIG. 1, the first sub-line BRS_H may serve as a bridge for connection to the data line DL extending in the second direction DR2, which will be described in FIG. 9G.

Referring to FIGS. 8 and 9G, a seventh conductive layer CL7 may include a seventh pattern P7, an upper line PL1-V of the first power line PL1, the second sub-line BRS_V, and the data line DL. The seventh conductive layer CL7 may be disposed on the sixth insulating layer INS6 described in FIG. 7 and may be covered by the seventh insulating layer INS7.

FIG. 9G illustrates seventh contact holes CNT7 that penetrate the seventh insulating layer INS7 described in FIG. 7. The seventh contact holes CNT7 may penetrate the seventh insulating layer INS7 to expose conductive patterns included in the seventh conductive layer CL7. The seventh contact hole CNT7 may overlap the seventh pattern P7.

One end portion of the seventh pattern P7 may be connected to an opposite end portion of the second pattern P2 through the sixth contact hole CNT6. An opposite end portion of the seventh pattern P7 may be connected to the first electrode AE of the light emitting element OLED (see FIG. 7) through the seventh contact hole CNT7.

The upper line PL1-V of the first power line PL1 may extend in the second direction DR2. A portion of the upper line PL1-V may be connected to the lower line PL1-H through the sixth contact hole CNT6.

The second sub-line BRS_V may extend in the second direction DR2 and may be disposed between the upper line PL1-V and the data line DL. Although not illustrated, the second sub-line BRS_V may be connected to the first sub-line BRS_H through a contact hole penetrating the sixth insulating layer INS6 and may be connected to the data line DL. According to an embodiment, at least one of the first sub-line BRS_H and the second sub-line BRS_V may be omitted.

The data line DL may extend in the second direction DR2. A portion of the data line DL may be connected to an opposite end portion of the fifth pattern P5 through the sixth contact hole CNT6.

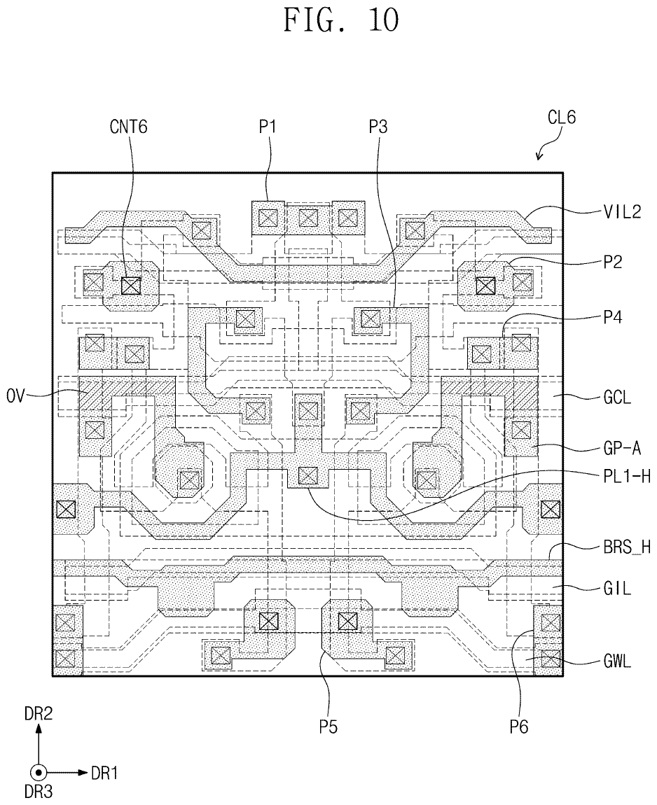

FIG. 10 is a plan view illustrating the conductive patterns included in the conductive layers of the pixel circuit according to one or more embodiments of the present disclosure. FIG. 10 illustrates an embodiment of the sixth insulating layer CL6 which is the same as that of FIG. 9F.

Referring to FIG. 10, the sixth conductive layer CL6 may include the first to sixth patterns P1 to P6, the second initialization line VIL2, a gate pattern GP-A, the lower line PL1-H of the first power line PL1, and the first sub-line BRS_H. The sixth conductive layer CL6 may be disposed on the fifth insulating layer INS5 described in FIG. 7 and may be covered by the sixth insulating layer INS6.

FIG. 9F illustrates the sixth contact holes CNT6 penetrating the sixth insulating layer INS6 described in FIG. 7. The sixth contact holes CNT6 may penetrate the sixth insulating layer INS6 to expose the conductive patterns included in the sixth conductive layer CL6. The sixth contact holes CNT6 may overlap the second pattern P2, the lower line PL1-H, and the fifth pattern P5.

The central portion of the first pattern P1 may be connected to the portion of the first conductive layer CL1, which protrudes from the seventh semiconductor layer M7, through the first contact hole CNT1. Further, the end portion of the first pattern P1 may be connected to the bias line VBL through the fifth contact hole CNT5.

The one end portion of the second pattern P2 may be connected to the portion of the first conductive layer CL1, which protrudes from the eighth semiconductor layer M8, through the first contact hole CNT1.

The one end portion of the third pattern P3 may be connected to the portion of the first conductive layer CL1, which protrudes between the sixth semiconductor layer M6 and the seventh semiconductor layer M7, through the first contact hole CNT1. The opposite end portion of the third pattern P3 may be connected to the portion of the first conductive layer CL1, which protrudes from the first semiconductor layer M1.

The one end portion of the fourth pattern P4 may be connected to the portion of the first conductive layer CL1, which protrudes from the fifth semiconductor layer M5, through the first contact hole CNT1. The opposite end portion of the fourth pattern P4 may be connected to the portion of the fourth conductive layer CL4, which protrudes from the third semiconductor layer M3, through the fourth contact hole CNT4.

The one end portion of the fifth pattern P5 may be connected to the portion of the first conductive layer CL1, which protrudes from the second semiconductor layer M2, through the first contact hole CNT1.

The one end portion of the sixth pattern P6 may be connected to the portion of the fourth conductive layer CL4, which protrudes from the fourth semiconductor layer M4, through the fourth contact hole CNT4. The opposite end portion of the sixth pattern P6 may be connected to the first initialization line VIL1 through the fifth contact hole CNT5.

The second initialization line VIL2 may be connected to the portion of the first conductive layer CL1, which protrudes from the eighth semiconductor layer M8, through the first contact hole CNT1.

One end portion of the gate pattern GP-A may be connected to the electrode pattern GE through the second contact hole CNT2 overlapping the opening OP. An opposite end portion of the gate pattern GP-A may be connected to the portion of the fourth conductive layer CL4, which protrudes from the third semiconductor layer M3, through the fourth contact hole CNT4.

In an embodiment, the gate pattern GP-A may be disposed on the same layer as the second initialization line VIL2. The gate pattern GP-A may not overlap the initialization scan line GIL and the bias scan line GBL on a plane. In an embodiment, a portion OV of the gate pattern GP-A may overlap the compensation scan line GCL. A parasitic cap may be formed between the portion OV of the gate pattern GP-A and the compensation scan line GCL, and therefore the brightness of the display panel DP may be easily adjusted.

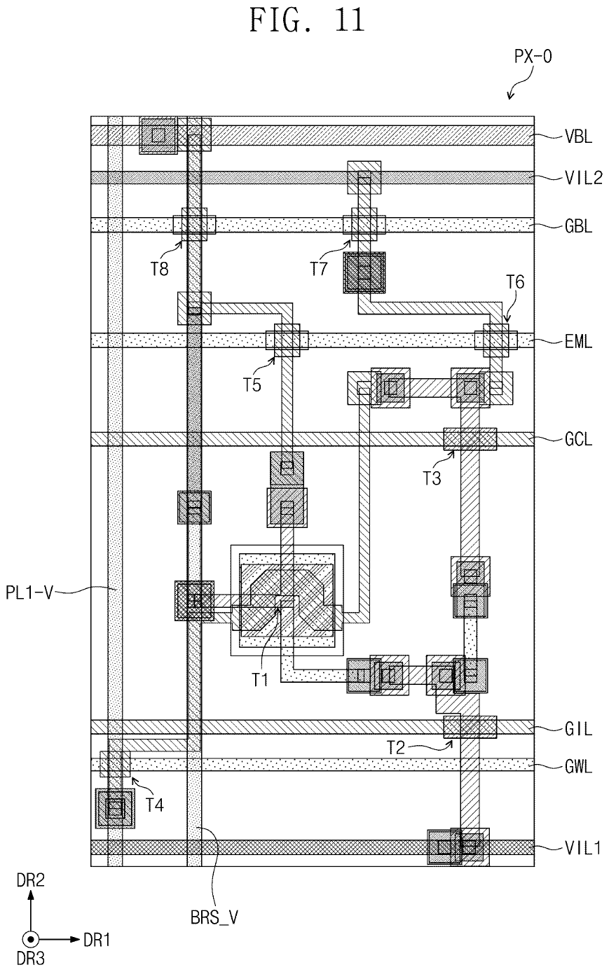

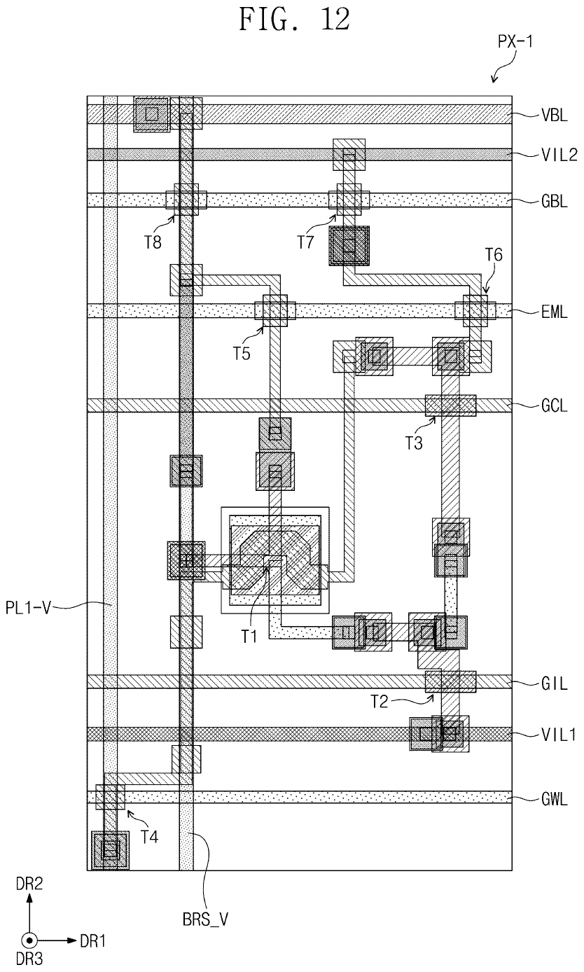

FIGS. 11 to 14 are schematic plan views illustrating an arrangement relationship of signal lines included in the pixel circuit according to one or more embodiments of the present disclosure. The same and/or similar reference numerals are used for the same and/or similar components as those described in FIGS. 1 to 9G, and duplicated descriptions thereof will be omitted.

FIGS. 11 to 14 schematically illustrate the signal lines included in the pixel circuit PC (see FIG. 5) of the pixel PX described in FIG. 4. FIGS. 11 to 14 schematically illustrate contact portions (quadrangular shape) connected between the transistors T1 to T8 and the signal lines.

FIGS. 11 to 14 illustrate the upper line PL1-V of the first power line PL1 and the second sub-line BRS_V included in the seventh conductive layer CL7, which each extend in the second direction DR2 and are sequentially arranged in the first direction DR1.

Referring to FIG. 11, a pixel PX-0 according to an embodiment may include the bias line VBL, the second initialization line VIL2, the bias scan line GBL, the light emitting line EML, the compensation scan line GCL, the initialization scan line GIL, the writing scan line GWL, and the first initialization line VIL1, which each extend in the first direction DR1 and are sequentially arranged in the second direction DR2.

According to an embodiment, on a plane defined by the first direction DR1 and the second direction DR2, the bias line VBL may be disposed above the second initialization line VIL2. The first transistor T1 may be disposed between the compensation scan line GCL and the initialization scan line GIL. The writing scan line GWL may be disposed below the initialization scan line GIL, and the first initialization line VIL1 may be disposed below the writing scan line GWL.

Referring to FIG. 12, a pixel PX-1 according to an embodiment may include the bias line VBL, the second initialization line VIL2, the bias scan line GBL, the light emitting line EML, the compensation scan line GCL, the initialization scan line GIL, the first initialization line VIL1, and the writing scan line GWL, which each extend in the first direction DR1 and are sequentially arranged in the second direction DR2.

According to an embodiment, on the plane defined by the first direction DR1 and the second direction DR2, the bias line VBL may be disposed above the second initialization line VIL2. The first transistor T1 may be disposed between the compensation scan line GCL and the initialization scan line GIL.

According to an embodiment, on the plane defined by the first direction DR1 and the second direction DR2, the first initialization line VIL1 may be disposed below the initialization scan line GIL, and the writing scan line GWL may be disposed below the first initialization line VIL1.

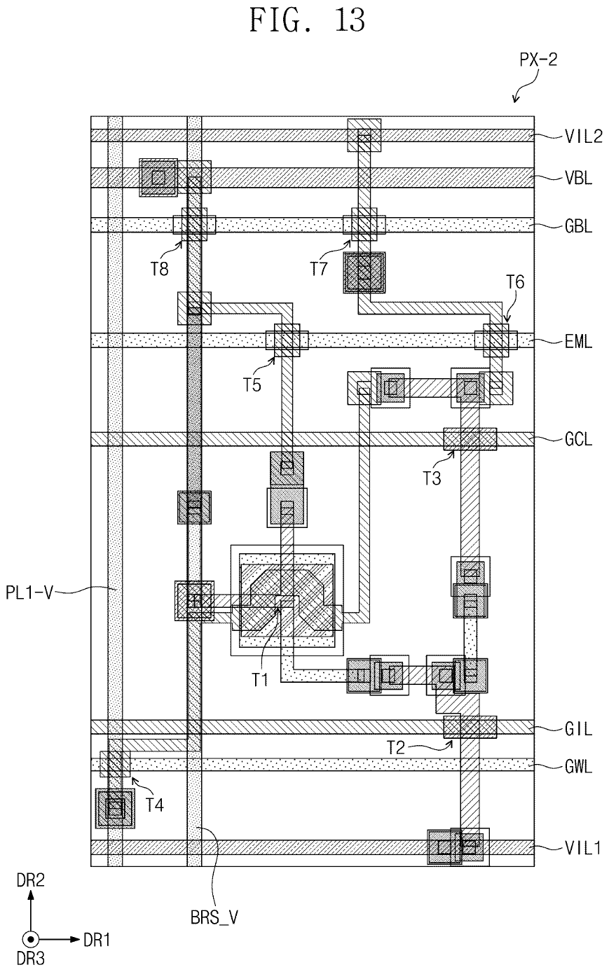

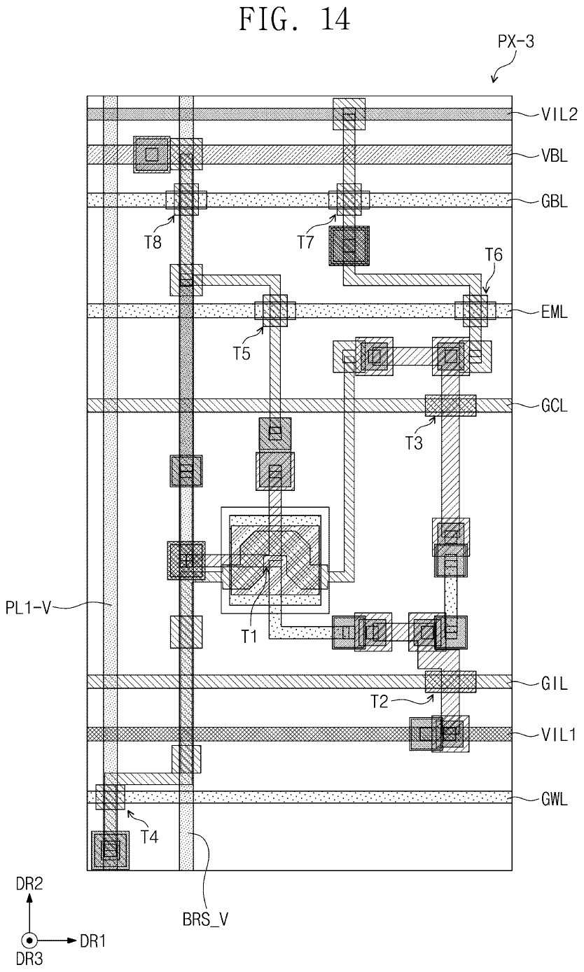

Referring to FIG. 13, a pixel PX-2 according to an embodiment may include the second initialization line VIL2, the bias line VBL, the bias scan line GBL, the light emitting line EML, the compensation scan line GCL, the initialization scan line GIL, the writing scan line GWL, and the first initialization line VIL1, which each extend in the first direction DR1 and are sequentially arranged in the second direction DR2.

According to an embodiment, on a plane defined by the first direction DR1 and the second direction DR2, the second initialization line VIL2 may be disposed above the bias line VBL. The first transistor T1 may be disposed between the compensation scan line GCL and the initialization scan line GIL.

According to an embodiment, on the plane defined by the first direction DR1 and the second direction DR2, the writing scan line GWL may be disposed below the initialization scan line GIL, and the first initialization line VIL1 may be disposed below the writing scan line GWL.

Referring to FIG. 14, a pixel PX-3 according to an embodiment may include the second initialization line VIL2, the bias line VBL, the bias scan line GBL, the light emitting line EML, the compensation scan line GCL, the initialization scan line GIL, the first initialization line VIL1, and the writing scan line GWL, which each extend in the first direction DR1 and are sequentially arranged in the second direction DR2.

According to an embodiment, on a plane defined by the first direction DR1 and the second direction DR2, the second initialization line VIL2 may be disposed above the bias line VBL. The first transistor T1 may be disposed between the compensation scan line GCL and the initialization scan line GIL.

According to an embodiment, on the plane defined by the first direction DR1 and the second direction DR2, the first initialization line VIL1 may be disposed below the initialization scan line GIL, and the writing scan line GWL may be disposed below the first initialization line VIL1.

According to one or more embodiments of the present disclosure, an electronic device including a display panel having improved brightness by setting an arrangement relationship of signal lines arranged inside a pixel circuit may be provided.

Although the description has been made above with reference to example embodiments of the present disclosure, it would be understood that those skilled in the art or those having ordinary knowledge in the art may variously modify and change the present disclosure without departing from the spirit and technical scope of the present disclosure described in the appended claims.

Thus, the technical scope of the present disclosure is not limited to the detailed description of the specification but should be defined by the appended claims and their equivalents.

What is claimed is:

1. A display panel comprising:
a substrate;
insulating layers on the substrate;
signal lines between the insulating layers;
transistors connected to the signal lines; and
a light emitting element connected to the transistors,
wherein the signal lines comprise a first initialization line, a bias line, a bias scan line, a light emitting line, a compensation scan line, an initialization scan line, a writing scan line, and a second initialization line, which extend in a first direction and are arranged in a second direction crossing the first direction, and a data line extending in the second direction, and
wherein a driving transistor among the transistors is between the compensation scan line and the initialization scan line on a plane defined by the first direction and the second direction.

2. The display panel of claim 1, wherein, among the transistors, a compensation transistor connected to the compensation scan line is spaced apart from a first initialization transistor connected to the initialization scan line in the second direction with the driving transistor interposed therebetween.

3. The display panel of claim 2, wherein semiconductor layers included in the compensation transistor and the first initialization transistor comprise a metal oxide, and semiconductor layers included in remaining transistors of the transistors comprise polysilicon.

4. The display panel of claim 3, wherein the semiconductor layers comprising the metal oxide and the semiconductor layers comprising the polysilicon are different layers.

5. The display panel of claim 4, further comprising:
a gate pattern connecting the driving transistor and the compensation transistor,
wherein the gate pattern is on a same layer as the first initialization line.

6. The display panel of claim 5, wherein the gate pattern does not overlap, on the plane, the initialization scan line, the compensation scan line, and the writing scan line.

7. The display panel of claim 5, wherein, on the plane, the gate pattern does not overlap the initialization scan line and the writing scan line, and a portion of the gate pattern overlaps the compensation scan line.

8. The display panel of claim 5, wherein the insulating layers comprise a buffer layer and first to seventh insulating layers that are sequentially laminated, and
wherein the display panel further comprises:
a first conductive layer on the buffer layer and covered by the first insulating layer;
a second conductive layer on the first insulating layer and covered by a second insulating layer;
a third conductive layer on the second insulating layer and covered by a third insulating layer;
a fourth conductive layer on the third insulating layer and covered by a fourth insulating layer;
a fifth conductive layer on the fourth insulating layer and covered by a fifth insulating layer;
a sixth conductive layer on the fifth insulating layer and covered by a sixth insulating layer; and
a seventh conductive layer on the sixth insulating layer and covered by the seventh insulating layer.

9. The display panel of claim 8, wherein the semiconductor layers comprising the polysilicon are included in the first conductive layer.

10. The display panel of claim 9, wherein the bias scan line, the light emitting line, the writing scan line, and a gate electrode included in the driving transistor are included in the second conductive layer.

11. The display panel of claim 10, wherein each of the compensation scan line and the initialization scan line comprises a lower layer and an upper layer,
wherein a dummy electrode included in the lower layer of the compensation scan line, the lower layer of the initialization scan line, and the driving transistor is included in the third conductive layer, the dummy electrode overlapping the gate electrode in a third direction crossing the first direction and the second direction, and
wherein an opening, through which the gate electrode is exposed, is defined in the dummy electrode.

12. The display panel of claim 11, wherein the semiconductor layers comprising the metal oxide are included in the fourth conductive layer.

13. The display panel of claim 12, wherein the bias line, the upper layer of the compensation scan line, the upper layer of the initialization scan line, and the second initialization line are included in the fifth conductive layer.

14. The display panel of claim 13, wherein the first initialization line and the gate pattern are included in the sixth conductive layer.

15. The display panel of claim 14, wherein the data line is included in the seventh conductive layer.

16. The display panel of claim 15, further comprising:
a first power line configured to provide a first power voltage to the driving transistor,
wherein the first power line comprises a lower line included in the sixth conductive layer and extending in the first direction and an upper line included in the seventh conductive layer, extending in the second direction, and connected to the lower line through a contact hole defined in the sixth insulating layer.

17. The display panel of claim 16, wherein the lower line is connected to the dummy electrode through a contact hole penetrating the third insulating layer, the fourth insulating layer, and the fifth insulating layer.

18. The display panel of claim 14, wherein one end portion of the gate pattern is connected to the gate electrode included in the driving transistor through a first contact hole, the first contact hole overlapping the opening and penetrating the second insulating layer, the third insulating layer, the fourth insulating layer, and the fifth insulating layer, and
wherein an opposite end portion of the gate pattern is connected to a semiconductor layer comprising the metal oxide through a second contact hole penetrating the fourth insulating layer and the fifth insulating layer.

19. The display panel of claim 14, further comprising:
a first sub-line included in the sixth conductive layer and extending in the first direction; and
a second sub-line included in the seventh conductive layer, connected to the first sub-line through a contact hole defined in the sixth insulating layer, and extending in the second direction,
wherein the second sub-line is connected to the data line.

20. The display panel of claim 1, wherein the light emitting element comprises a first electrode connected to the driving transistor, a second electrode on the first electrode, and a light emitting layer between the first electrode and the second electrode.

21. A display panel comprising:
signal lines;
transistors connected to the signal lines; and
a light emitting element connected to the transistors,
wherein the signal lines comprise a bias line, a first initialization line, a bias scan line, a light emitting line, a compensation scan line, an initialization scan line, a writing scan line, and a second initialization line which extend in a first direction and are arranged in a second direction crossing the first direction, and a data line extending in the second direction, and
wherein a driving transistor among the transistors is between the compensation scan line and the initialization scan line on a plane defined by the first direction and the second direction.

22. The display panel of claim 21, wherein, on the plane, the bias line is above the first initialization line, and
wherein the bias scan line is below the first initialization line.

23. The display panel of claim 22, wherein, on the plane, the writing scan line is below the initialization scan line, and the second initialization line is below the writing scan line.

24. The display panel of claim 23, wherein, on the plane, the second initialization line is below the initialization scan line, and the writing scan line is below the second initialization line.

25. The display panel of claim 21, wherein, on the plane, the first initialization line is above the bias line, and
wherein the bias scan line is below the bias line.

26. The display panel of claim 25, wherein, on the plane, the second initialization line is below the initialization scan line, and the writing scan line is below the second initialization line.

27. An electronic device comprising:
a window; and
a display panel below the window,
wherein the display panel comprises:
a substrate;
insulating layers on the substrate;
signal lines between the insulating layers;
transistors connected to the signal lines; and
a light emitting element connected to the transistors,
wherein the signal lines comprise a first initialization line, a bias line, a bias scan line, a light emitting line, a compensation scan line, an initialization scan line, a writing scan line, and a second initialization line, which extend in a first direction and are arranged in a second direction crossing the first direction, and a data line extending in the second direction, and
wherein a driving transistor among the transistors is between the compensation scan line and the initialization scan line on a plane defined by the first direction and the second direction.

28. The electronic device of claim 27, wherein, among the transistors, a compensation transistor connected to the compensation scan line is spaced apart from a first initialization transistor connected to the initialization scan line in the second direction with the driving transistor interposed therebetween.

29. The electronic device of claim 28, wherein semiconductor layers included in the compensation transistor and the first initialization transistor comprise a metal oxide, and semiconductor layers included in remaining transistors of the transistors comprise polysilicon.

30. The electronic device of claim 29, wherein the semiconductor layers comprising the metal oxide and the semiconductor layers comprising the polysilicon are different layers.

31. The electronic device of claim 30, further comprising:
a gate pattern connecting the driving transistor and the compensation transistor,
wherein the gate pattern is on a same layer as the first initialization line.

32. The electronic device of claim 31, wherein the gate pattern does not overlap, on the plane, the initialization scan line, the compensation scan line, and the writing scan line.

33. The electronic device of claim 31, wherein, on the plane, the gate pattern does not overlap the initialization scan line and the writing scan line, and a portion of the gate pattern overlaps the compensation scan line.
